(19) United States
(12) Patent Application Publication
(10) Pub. No.: US 2026/0024724 A1
(43) Pub. Date: Jan. 22, 2026

(54) DEPOSITION APPARATUS

(71) Applicant: Samsung Display Co., Ltd., Yongin-Si (KR)

(72) Inventors: CHOELMIN JANG, Yongin-si (KR); JUNGGON KIM, Yongin-si (KR)

(21) Appl. No.: 19/180,583

(22) Filed: Apr. 16, 2025

(30) Foreign Application Priority Data
Jul. 17, 2024 (KR) 10-2024-0094337

(51) Int. Cl. H01J 37/32; C23C 16/455; C23C 16/50

(52) U.S. Cl. CPC H01J 37/3244; C23C 16/45563; C23C 16/50; H01J 2237/332

(57) ABSTRACT

Disclosed is a deposition apparatus including a stage, and a nozzle assembly disposed on the stage, and including an electrode part extending in a first direction and a nozzle part disposed under the electrode part. A passage is defined in the electrode part, the passage includes a main passage defined on an upper surface of the electrode part, and extending in a downward direction, a first passage extending from a lower portion of the main passage in the first direction, first connection passages extending in the downward direction from a (1-1)-th area and a (1-2)-th area being adjacent to opposite sides of the first passage, which are opposite in the first direction, and second passages extending in the first direction from lower portions of the first connection passages, and the nozzle part is disposed under the second passages.

### CROSS-REFERENCE TO RELATED APPLICATIONS

This application claims priority under 35 U.S.C. § 119 to Korean Patent Application No. 10-2024-0094337 filed on Jul. 17, 2024, in the Korean Intellectual Property Office, the disclosures of which are incorporated by reference herein in their entireties.

### BACKGROUND

Embodiments of the present disclosure described herein relate to a deposition apparatus.

Display devices, such as televisions, monitors, smartphones, and tablets, which provide images to the users include display panels that display images. Various display panels, such as liquid crystal display panels, organic light emitting display panels, electro-wetting display panels, and electrophoretic display panels, are being developed as display panels.

Processes for manufacturing display panels include plasma-enhanced chemical vapor deposition processes and plasma-enhanced atomic layer deposition processes of depositing a process gas into a plasma state by applying a high voltage while ejecting the process gas to a surface of a target substrate.

### SUMMARY

Embodiments of the present disclosure provide a deposition apparatus that may deposit a thin film with a uniform thickness on a substrate.

According to an embodiment, a deposition apparatus includes a stage, and a nozzle assembly disposed on the stage, and including an electrode part extending in a first direction and a nozzle part disposed under the electrode part. A passage is defined in the electrode part. The passage includes a main passage defined on an upper surface of the electrode part, and extending in a downward direction, a first passage extending from a lower portion of the main passage in the first direction, first connection passages extending in the downward direction from a (1-1)-th area and a (1-2)-th area being adjacent to opposite sides of the first passage, which are opposite in the first direction, and second passages extending in the first direction from lower portions of the first connection passages, and the nozzle part is disposed under the second passages.

According to an embodiment, a deposition apparatus includes a stage, an accommodation part disposed on the stage, and including a body, in which an accommodation groove is defined, and a support plate disposed on a lower surface of the body, a nozzle assembly extending in a first direction, and disposed in the accommodation groove, and a gas supply part disposed on an upper surface of the accommodation part, and opposite sides of the nozzle assembly, which are opposite to each other in the first direction, are disposed in support grooves defined in the support plate.

### BRIEF DESCRIPTION OF THE FIGURES

The above and other features of the present disclosure will become apparent by describing in detail embodiments thereof with reference to the accompanying drawings.

FIG. 1 is a perspective view of a deposition apparatus according to an embodiment of the present disclosure.

FIG. 2 is an exploded perspective view of a gas ejection part illustrated in FIG. 1.

FIG. 3 is an exploded perspective view of a nozzle assembly illustrated in FIG. 2.

FIG. 4 is a cross-sectional view of an electrode part and a nozzle part according to an embodiment of the present disclosure.

FIG. 5 is a cross-sectional view of an electrode part and a nozzle part according to an embodiment of the present disclosure.

FIG. 6A is a cross-sectional view of a part corresponding to line IV-IV′ illustrated in FIG. 2.

FIG. 6B is a cross-sectional view of a part corresponding to line V-V′ illustrated in FIG. 2.

FIG. 7 is an exploded perspective view of a first insulation part illustrated in FIG. 3.

FIG. 8 is a perspective view of a portion of an accommodation part and a gas supply part illustrated in FIG. 2.

FIG. 9 is a perspective view of a gas supply part, an accommodation part, and a nozzle assembly illustrated in FIG. 2.

FIG. 10A is a side view of a gas ejection part illustrated in FIG. 9.

FIG. 10B is a side view of a gas ejection part according to an embodiment of the present disclosure.

FIG. 11 is a view illustrating a process of depositing on a substrate by using a deposition apparatus according to an embodiment of the present disclosure.

FIGS. 12A, 12B, and 12C are views schematically illustrating an atomic layer deposition method.

FIGS. 13A and 13B are cross-sectional views of a nozzle assembly according to an embodiment of the present disclosure.

### DETAILED DESCRIPTION

In the specification, when it is mentioned that a component (or an area, a layer, a part, or the like) is “disposed on”, “connected to”, or “coupled to” another component, it means that the former component may be directly disposed on, connected to, or coupled to the latter component or a third component may be disposed between the components.

The same reference numerals denote the same components. Furthermore, in the drawings, thicknesses, ratios, dimensions of the components are exaggerated for an effective description of the technical contents. The term “and/or” includes one or more combinations that may be defined by the associated components.

Furthermore, in describing the various components, the terms, such as first and second may be used, but the present disclosure is not limited by the terms. The terms are simply for distinguishing the components. For example, a first component may be named a second component, and similarly the second component also may be named the first component while not departing from the scope of the present disclosure. A singular expression includes a plural expression unless an exemption is explicitly described in the context.

Furthermore, the terms, such as “under”, “below”, “on”, and “above”, are used to describe an associative relationship between the components illustrated in the drawings. The terms are relative concepts, and are described with respect to directions indicated in the drawings.

When the terms, such as “comprise” and/or “comprising”, is used in the specification, it should be understood that they specify presence of the above-mentioned features, numbers, steps, operations, components, parts, and/or combinations thereof, and do not exclude presence or addition of one or more other numbers, steps, operations, components, parts, and/or combinations thereof.

Unless otherwise defined, all terms, including technical and scientific terms, used herein have the same meaning as commonly understood by those skilled in the art to which the present disclosure pertains. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein.

Hereinafter, embodiments of the present disclosure will be described with reference to the drawings.

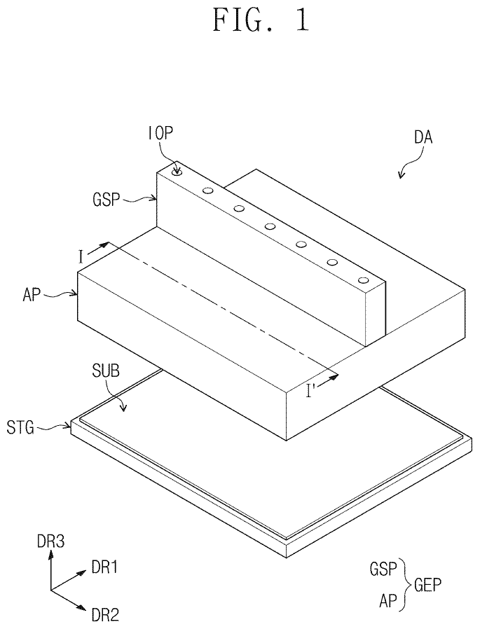

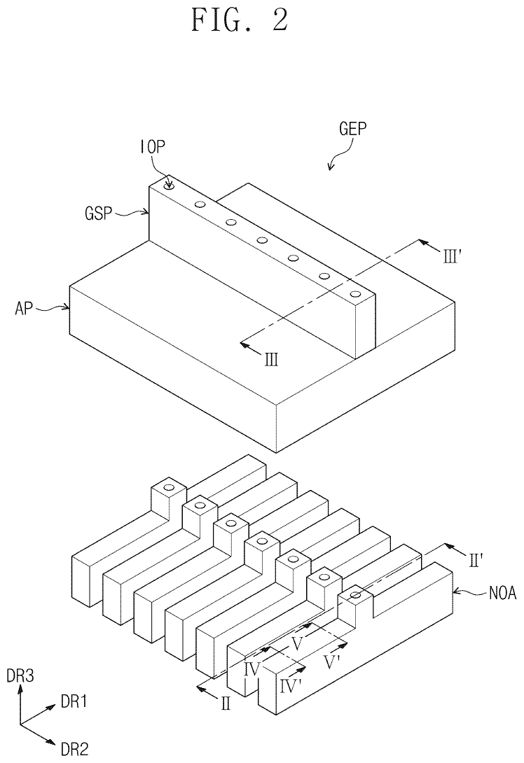

FIG. 1 is a perspective view of a deposition apparatus DA according to an embodiment of the present disclosure. FIG. 2 is an exploded perspective view of a gas ejection part GEP illustrated in FIG. 1.

Referring to FIG. 1, the deposition apparatus DA may include a stage STG and a gas ejection part GEP (see FIG. 2). Although not illustrated, the deposition apparatus DA may be accommodated in a chamber (not illustrated).

The stage STG may have a rectangular parallelepiped shape. An upper surface of the stage STG may be parallel to a plane that is defined by a first direction DR1 and a second direction DR2 that crosses the first direction DR1. However, this is exemplary, and a shape of the stage STG is not limited thereto.

Hereinafter, a direction that is substantially perpendicular to a plane defined by the first and second directions DR1 and DR2 is defined as a third direction DR3. Furthermore, in the specification, “when viewed on a plane” may be defined as a state, in which is viewed from the third direction DR3.

The stage STG may support a substrate SUB. The substrate SUB may be reciprocated in the second direction DR2 and an opposite direction to the second direction DR2 under the gas injection part GEP (see FIG. 2). To move the substrate SUB, the stage STG may be implemented as a movable stage.

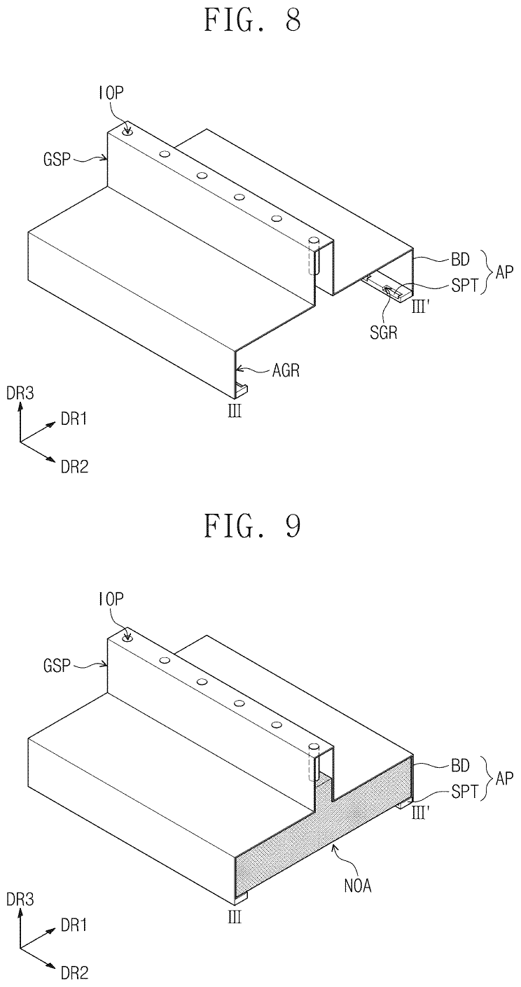

Referring to FIGS. 1 and 2, the gas injection part GEP may be disposed on the substrate SUB. The gas injection part GEP may include an accommodation part AP, the gas supply part GSP, and a plurality of nozzle assemblies NOA. By way of example, the accommodation part AP may have a rectangular parallelepiped shape, but the shape of the accommodation part AP is not limited thereto. Although not illustrated in FIG. 2, an accommodation groove AGR (see FIG. 8) for accommodating the nozzle assemblies NOA may be defined on a lower surface of the accommodation part AP. The accommodation groove AGR (see FIG. 8) will be described in detail below.

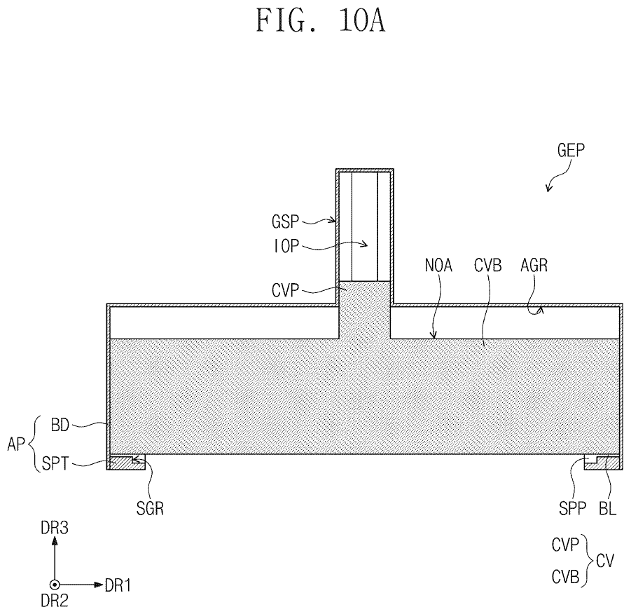

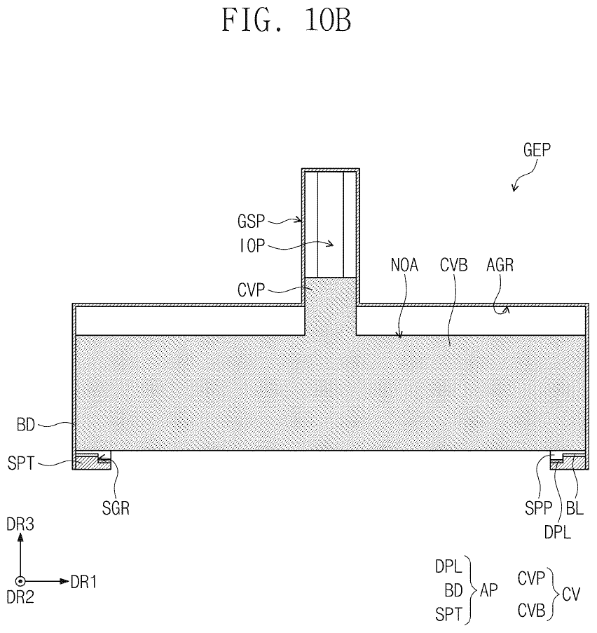

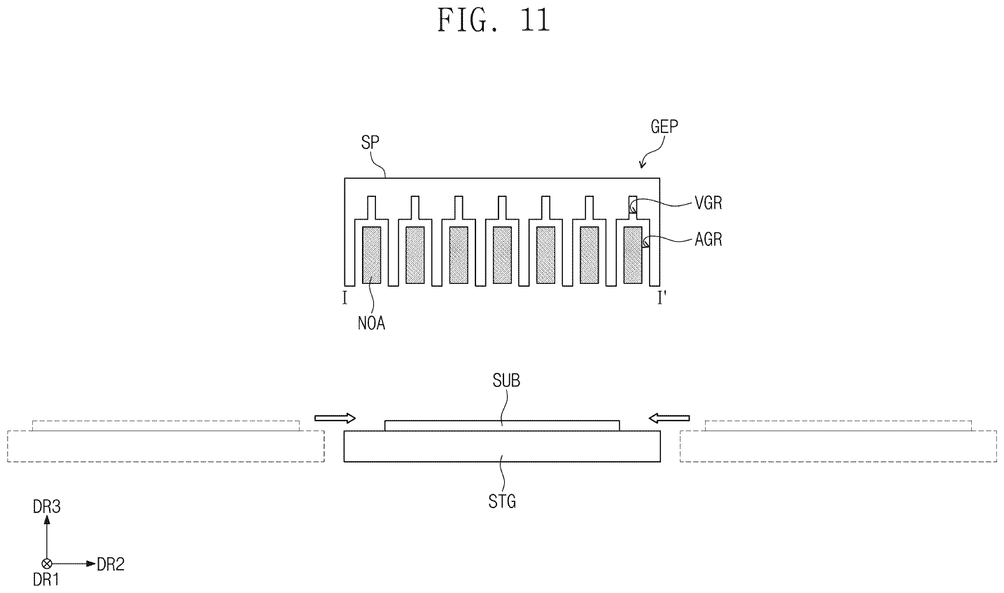

The gas supply part GSP may be disposed on an upper surface of the accommodation part AP. The gas supply part GSP may have a rectangular parallelepiped shape that extends longer in the second direction DR2 than in the first direction DR1. The gas supply part GSP may include a plurality of gas supply pipes IOP. The gas supply pipes IOP may be arranged in the second direction DR2. Although not illustrated, the gas supply pipes IOP may be connected to the nozzle assemblies NOA. The gas supply part GSP may supply gas that is received from an outside to the nozzle assemblies NOA. This will be described in detail with reference to FIGS. 9 and 10A.

The nozzle assemblies NOA may be disposed in an accommodation groove AGR (see FIG. 8) that is defined on a lower surface of the accommodation part AP. The nozzle assemblies NOA may extend in the first direction DR1, and may be arranged in the second direction DR2. A length of the nozzle assemblies NOA in the first direction DRI may correspond to a length of the substrate SUB in the first direction DR1.

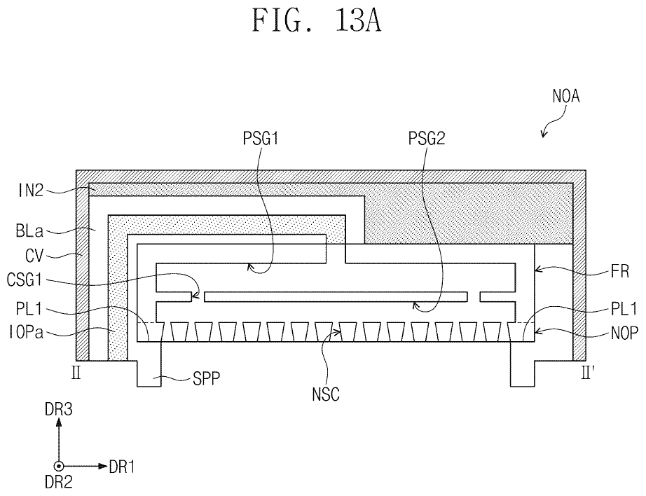

The nozzle assemblies NOA that receive the gas from the gas supply part GSP may be fixed on the substrate SUB by the accommodation part AP, and may eject the gas into the substrate SUB. The nozzle assemblies NOA may form a thin film on the substrate SUB through an automatic layer deposition (ALD) process of ejecting gas. In the order in the second direction DR2, the odd-numbered nozzle assembly NOA may eject a reaction gas. The even-numbered nozzle assembly NOA may eject a source gas. The reaction gas may react with the source gas on the substrate SUB. The atomic layer deposition process will be described in detail with reference to FIGS. 12A to 12C.

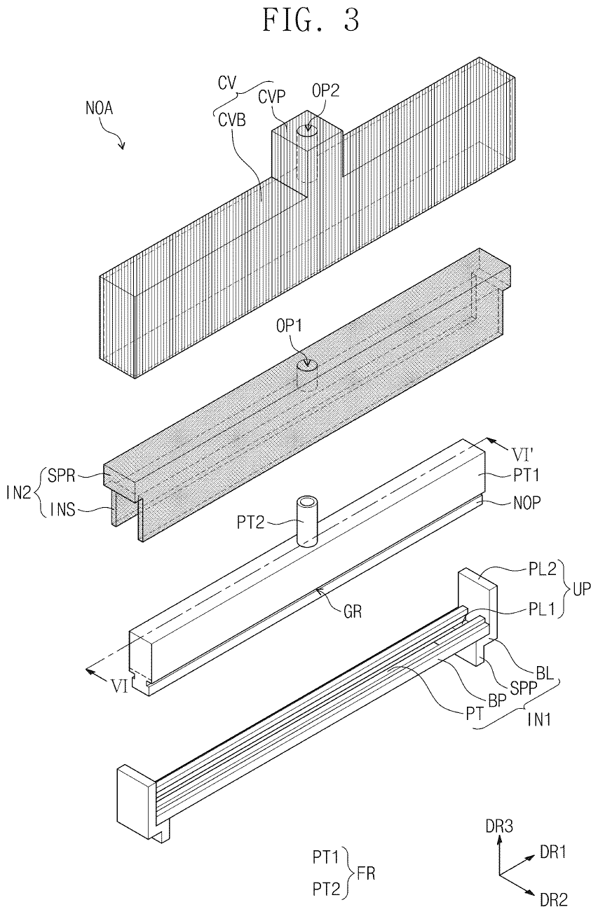

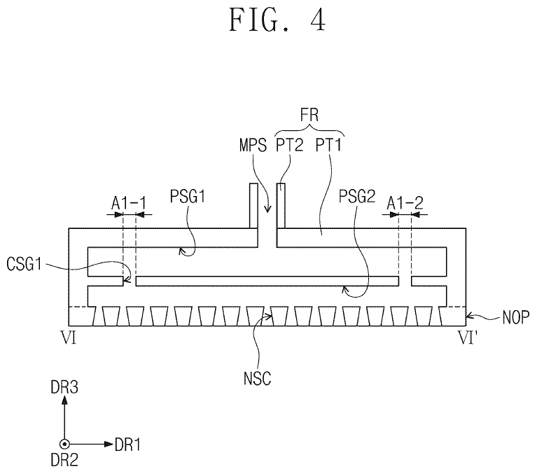

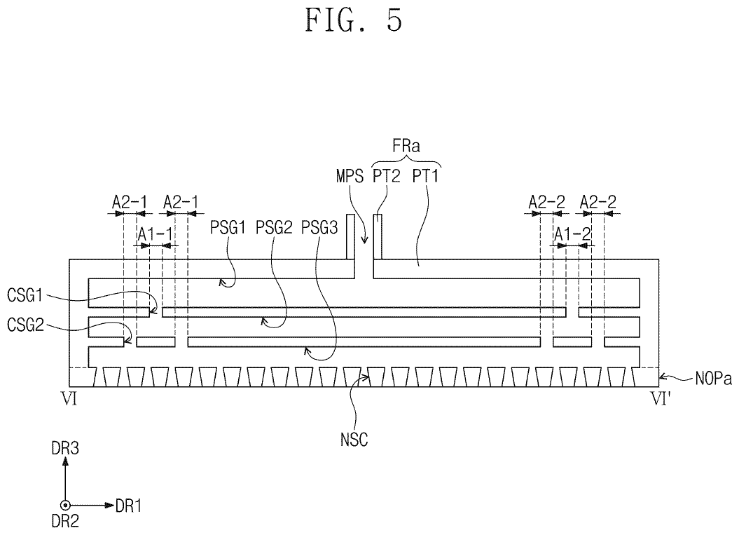

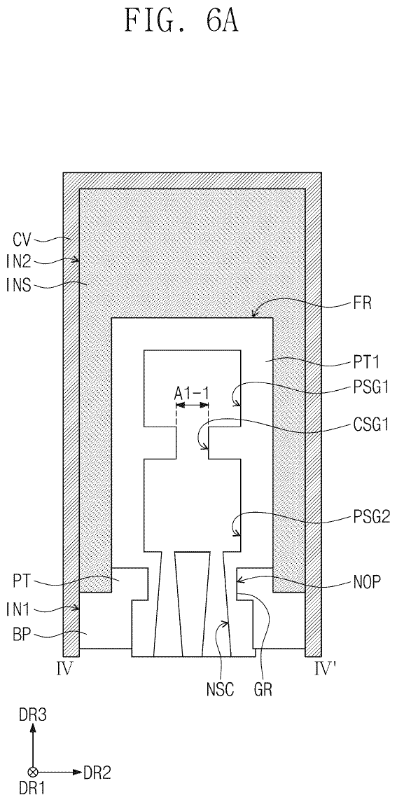

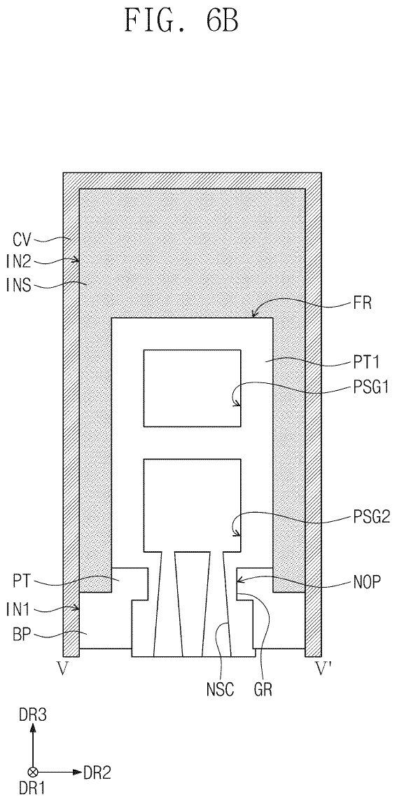

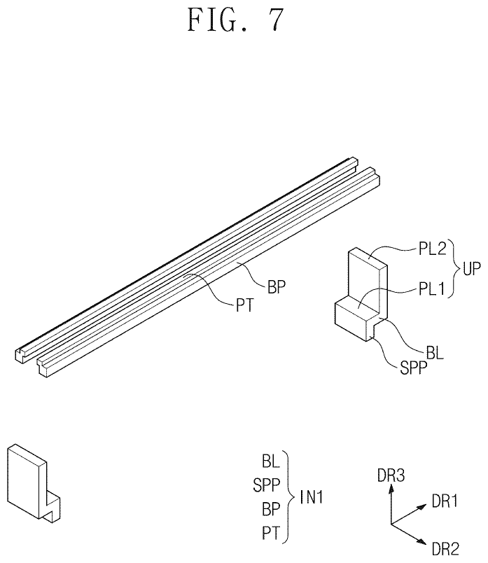

FIG. 3 is an exploded perspective view of a nozzle assembly NOA illustrated in FIG. 2. FIG. 4 is a cross-sectional view of an electrode part FR and a nozzle part NOP according to an embodiment of the present disclosure. FIG. 5 is a cross-sectional view of an electrode part FRa and a nozzle part NOPa according to an embodiment of the present disclosure. FIG. 6A is a cross-sectional view of a part corresponding to line IV-IV′ illustrated in FIG. 2. FIG. 6B is a cross-sectional view of a part corresponding to line V-V′ illustrated in FIG. 2. FIG. 7 is an exploded perspective view of a first insulation part IN1 illustrated in FIG. 3.

By way of example, FIGS. 4 and 5 are cross-sectional views of parts corresponding to line VI-VI′ illustrated in FIG. 3.

For convenience of description, any one of the nozzle assemblies NOA of FIG. 2 will be described.

Referring to FIGS. 3 and 4, the nozzle assemblies NOA may include the electrode part FR, the nozzle part NOP, a first insulation part IN1, a second insulation part IN2, and a cover part CV. The electrode part FR may extend in the first direction DR1.

The electrode part FR may include a first part PT1 and a second part PT2. The first part PT1 may have a rectangular parallelepiped shape that extends in the first direction DR1, but the shape of the first part PT1 is not limited thereto.

The second part PT2 may be disposed on the first part PT1. The second part PT2 may be disposed on an upper surface of the first part PT1. The second part PT2 may overlap a center of the first part PT1. The second part PT2 may have a cylindrical shape, but the shape of the second part PT2 is not limited thereto.

Referring to FIGS. 4, 6A, and 6B, a main passage MPS, a first passage PSG1, a plurality of first connection passages CSG1, and a second passage PSG2 may be included in an interior of the electrode part FR. The main passage MPS may be defined by the second part PT2. The main passage MPS may extend in the third direction DR3.

The first passage PSG1, the first connection passage CSG1, and the second passage PSG2 may be defined in the first part PT1. The first passage PSG1 may extend in the first direction DR1 under the main passage MPS. Here, the meaning of “extend in the first direction DR1” is defined as being able to extend not only in the first direction DR1 but also in an opposite direction to the first direction DR1.

In the first passage PSG1, a (1-1)-th area A1-1 and a (1-2)-th area A1-2 may be defined. The (1-1)-th area A1-1 and the (1-2)-th area A1-2 may be defined as areas that are adjacent to opposite sides of the first passage PSG1, which are opposite to each other in the first direction DR1. The (1-1)-th area A1-1 and the (1-2)-th area A1-2 may be disposed between a center of the first passage PSG1 and opposite sides of the first passage PSG1, which are opposite to each other in the first direction DR1.

A first connection passages CSG1 may extend in the third direction DR3 in the (1-1)-th area A1-1 and the (1-2)-th area A1-2. The first connection passages CSG1 may extend in the downward direction in the (1-1)-th area Al-1 and the (1-2)-th area A1-2. The first connection passages CSG1 may be disposed between a center of the electrode part FR and opposite sides of the electrode part FR, which are opposite to each other in the first direction DR1. The first connection passages CSG1 may be disposed adjacent to opposite sides of the first passage PSG1, which are opposite to each other in the first direction DR1. The first passage PSG1 and the first connection passages CSG1 may be continuously defined in the third direction DR3.

The second passage PSG2 may extend in the first direction DRI under the first connection passages CSG1. The second passage PSG2 may be defined in the third direction DR3 to be continuous to the first connection passages CSG1.

As illustrated in FIG. 6A, in the (1-1)-th area A1-1 and the (1-2)-th area A1-2, the first passage PSG1 and the second passage PSG2 may be connected to each other by the first connection passages CSG1. As illustrated in FIG. 6B, in an area other than the (1-1)-th area A1-1 and the (1-2)-th area A1-2, the first passage PSG1 and the second passage PSG2 may be separated from each other.

The nozzle part NOP may be disposed under the electrode part FR. The nozzle part NOP and the electrode part FR may be formed substantially integrally, but are not limited thereto. A plurality of nozzle passages NSC may be defined in the nozzle part NOP. The nozzle passages NSC may be defined to be continuous to the second passage PSG2 in the third direction DR3.

When the gas is introduced into the electrode part FR through the main passage MPS, the gas may be diffused to the first connection passages CSG1 along the first passage PSG1. The gas diffused to the first connection passages CSG1 may be diffused to the second passage PSG2. The gas diffused to the second passage PSG2 may be ejected onto the substrate SUB through the nozzle passages NSC.

The electrode part FR may form the gas into a plasma state. For example, when the RF power source (not illustrated) is turned on and a high voltage is applied to the electrode part FR, the gas supplied to the first passage PSG1, the first connection passages CSG1, and the second passage PSG2 may be excited to a plasma state. The gas excited to the plasma state may be ejected to the substrate SUB through the nozzle passages NSC.

As the substrate SUB (see FIG. 1) becomes large, a length of the nozzle assembly NOA in the first direction DRI may increase. As the length of the nozzle assembly NOA increases, a length of the electrode part FR in the first direction DRI and a length of the nozzle part NOP in the first direction DRI may increase. When the gas supplied to the first passage PSG1 is ejected onto the substrate SUB through the nozzle passages NSC, the gas may not be sufficiently diffused to opposite sides of the electrode part FR, which are opposite to each other in the first direction DR1. Accordingly, because the gas is not uniformly ejected onto the substrate SUB, a thickness of the thin film deposited on the substrate SUB may not be uniform.

However, in the electrode part FR according to an embodiment of the present disclosure, gas may be supplied to the second passage PSG2 through the first connection passages CSG1 that are adjacent to opposite sides of the first passage PSG1, and the gas may be diffused to opposite sides of the second passage PSG2, which are opposite to each other in the first direction DR1. Accordingly, the gas may be uniformly ejected onto the substrate SUB through the nozzle passages NSC. Accordingly, a thickness of the thin film deposited on the substrate SUB may be uniform.

A description of, among the components illustrated in FIG. 5, components that are the same as those described above while the above-described drawings are referenced will be omitted or simplified.

Referring to FIG. 5, the electrode part FRa and the nozzle part NOPa illustrated in FIG. 5 may extend in the first direction DRI longer than the electrode part FR and the nozzle part NOP illustrated in FIG. 4. The substrate SUB deposited on by the electrode part FRa and the nozzle part NOPa illustrated in FIG. 5 may have a larger area than the substrate SUB deposited on by the electrode part FR and the nozzle part NOP illustrated in FIG. 4.

A plurality of (2-1)-th areas A2-1 and a plurality of (2-2)-th areas A2-2 may be defined in the second passage PSG2. The (2-1)-th areas A2-1 and the (2-2)-th areas A2-2 may be defined as areas that are disposed on an outer side of a center of the second passage PSG2. The (2-1)-th areas A2-1 and the (2-2)-th areas A2-2 may be disposed between opposite sides of the second passage PSG2, which are opposite to each other in the first direction DR1, and a center of the second passage PSG2.

When viewed from the second direction DR2, the (2-1)-th areas A2-1 may be disposed on a left side of the center of the second passage PSG2. By way of example, two (2-1)-th areas A2-1 are illustrated in FIG. 5, but the number of the (2-1)-th areas A2-1 is not limited thereto.

When viewed from the second direction DR2, the (2-2)-th areas A2-2 may be disposed on a right side of the center of the second passage PSG2. By way of example, two (2-2)-th areas A2-2 are illustrated in FIG. 5, but the number of the (2-2)-th areas A2-2 is not limited thereto.

Second connection passages CSG2 and a third passage PSG3 may be further defined in an interior of the electrode part FRa. The second connection passages CSG2 may extend in the third direction DR3 in the (2-1)-th and (2-2)-th areas A2-1 and A2-2. The second connection passages CSG2 may extend in the downward direction in the (2-1)-th and (2-2)-th areas A2-1 and A2-2. The second connection passages CSG2 may be disposed between a center of the electrode part FRa and opposite sides of the electrode part FRa, which are opposite to each other in the first direction DR1. The second connection passages CSG2 may be defined to be continuous to the second passage PSG2 in the third direction DR3. By way of example, two connection passages CSG2 are disposed on the left and right sides of the second passage PSG2, respectively, but the number of the second connection passages CSG2 is not limited thereto.

The third passage PSG3 may extend in the first direction DRI under the second connection passages CSG2. The third passage PSG3 may be defined to be continuous to the second connection passages CSG2 in the third direction DR3.

When the gas is supplied through the main passage MPS, the gas may be diffused to the first passage PSG1, the first connection passages CSG1, and the second passage PSG2. The gas diffused to the second passage PSG2 may be diffused to the third passage PSG3 through the second connection passages CSG2. The gas diffused to the third passage PSG3 may be ejected to the substrate SUB through the nozzle passages NSC.

As the second connection passages CSG2 and the third passage PSG3 are defined, the gas may be diffused to opposite sides of the electrode part FRa, which are opposite to each other in the first direction DR1, even when the area of the substrate SUB increases. Accordingly, the gas may be uniformly ejected onto the substrate SUB through the nozzle passages NSC. Accordingly, a thickness of the thin film deposited on the substrate SUB may be uniform.

Referring to FIGS. 3 and 6A, when viewed from the first direction DR1, the first insulation part IN1 may be disposed at opposite sides of the nozzle part NOP, which are opposite to each other in the second direction DR2. The first insulation part IN1 may include an insulating material. By way of example, the first insulation part IN1 may include ceramic, but the material of the first insulation part IN1 is not limited thereto.

The first insulation part IN1 may include a plurality of bar parts BP, a plurality of protrusions PT, a plurality of block parts BL, and a plurality of support parts SPP. The bar parts BP may extend in the first direction DR1, and may be disposed to be spaced apart from each other in the second direction DR2. When viewed from the first direction DR1, the nozzle part NOP may be disposed between the bar parts BP. By way of example, the bar parts BP may have a partial shape of a rectangular shape, but the shape of the bar parts BP is not limited thereto.

The protrusions PT may extend in the second direction DR2 from sides of the bar parts BP, which face each other. The protrusions PT may extend toward the nozzle parts NOP of the bar parts BP.

Grooves GR may be defined on opposite sides of the nozzle part NOP, which are opposite to each other in the second direction DR2. The grooves GR may extend in the first direction DR1. When viewed from the first direction DR1, the grooves GR may have a shape corresponding to a portion of a rectangular shape.

The protrusions PT may be disposed in the grooves GR. The protrusions PT may have shapes corresponding to the grooves GR. Substantially, the protrusions PT may be fitted into the grooves GR. Upper surfaces of the protrusions PT may support the nozzle part NOP and the electrode part FR. Accordingly, the bar parts BP may be fixed to the nozzle part NOP and the electrode part FR disposed on the nozzle part NOP.

Referring to FIGS. 3 and 7, the block parts BL may be arranged in the first direction DR1. The block parts BL may have an “L” shape when viewed from the second direction DR2, but the shape of the block parts BL is not limited thereto. Upper surfaces UP of the block parts BL may have a step. The upper surfaces UP of the block parts BL may include first planes PL1 and second planes PL2. Heights of the second planes PL2 may be higher than heights of the first planes PL1.

Opposite sides of the nozzle part NOP, which are opposite to each other in the first direction DR1, may be disposed on the upper surfaces UP of the block parts BL. The nozzle part NOP may be disposed on the first planes PL1. The block parts BL may support opposite sides of the nozzle part NOP, which are opposite to each other in the first direction DR1.

The block parts BL may be coupled to opposite sides of the bar parts BP, which are opposite to each other in the first direction DR1. The block parts BL and the bar parts BP may be coupled to each other to be detachable from each other.

When a length of the electrode part FR and a length of the nozzle part NOP increase, a length of the first insulation part IN1 may also increase. Then, when the block parts BL and the bar parts BP are integrally formed, it may not be easy to manufacture the first insulation part IN1. Furthermore, when an extent, e.g., length, of the substrate SUB (see FIG. 1) is changed, a change to the first insulation part IN1 having a length corresponding to an extent of the changed substrate SUB (see FIG. 1) may be required.

However, because the block parts BL and the bar parts BP are separately manufactured, only the length of the bar parts BP needs to be increased, so that the first insulation part IN1 may be easily manufactured. Furthermore, even when the extent of the substrate SUB (see FIG. 1) is changed, a deposition process may be performed on the substrate SUB of various sizes by replacing it with the bar parts BP having a length corresponding to the extent of the changed substrate SUB (see FIG. 1).

The support parts SPP may be disposed on lower surfaces of the block parts BL. The support parts SPP may be disposed adjacent to one of facing sides, among opposite sides of the block parts BL, which are opposite to each other in the first direction DR1. A size of the support parts SPP in the first direction DR1 may be smaller than a size of the block parts BL in the first direction DR1. Substantially, the support parts SPP may extend in the third direction DR3 on the lower surfaces of the block parts BL. Substantially, the support parts SPP and the block parts BL may be integrally formed.

The support parts SPP may be disposed on a support plate SPT (see FIG. 8), which will be described later, to fix the nozzle part NOP and the electrode part FR to the accommodation part AP. This will be described in detail with reference to FIGS. 8 and 9.

Referring to FIGS. 3, 6A, and 6B, the second insulation part IN2 may be disposed on the first insulation part IN1. The second insulation part IN2 may be disposed on the upper surfaces of the bar parts BP. Portions of the second insulation part IN2 may be disposed on the upper surfaces UP of the block parts BL. The second insulation part IN2 may be disposed on the electrode part FR. The second insulation part IN2 may cover the electrode part FR.

The second insulation part IN2 may include an insulating material. By way of example, the second insulation part IN2 may include Teflon, but a material of the second insulation part IN2 is not limited thereto.

The second insulation part IN2 may include an insulation part INS and a plurality of dummy parts SPR. The insulation part INS may be disposed on the upper surfaces of the bar parts BP. The insulation part INS may cover the upper surface of the electrode part FR and opposite side surfaces of the electrode part FR, which are opposite to each other in the second direction DR2. The upper surface of the electrode part FR and opposite side surfaces of the electrode part FR may not be exposed to an outside from the insulation part INS.

Because the electrode part FR is surrounded by the first insulation part IN1 and the second insulation part IN2, it may not be electrically connected to the cover part CV having a potential of 0. Accordingly, the electrode part FR may stably excite the gas into a plasma state.

A first opening OP1 may be defined on an upper surface of the insulation part INS. The first opening OP1 may be defined on a center of an upper surface of the insulation part INS. The first opening OP1 may overlap the second part PT2. When the insulation part INS covers the first part PT1, the second part PT2 may be disposed in the first opening OP1. Inner surfaces of the insulation part INS, which define the first opening OP1, may cover the second part PT2.

The dummy parts SPR may be disposed on opposite sides of the insulation part INS, which are opposite to each other in the first direction DR1. The dummy parts SPR may extend from the insulation part INS. When the insulation part INS is disposed on the upper surfaces of the bar parts BP, the dummy parts SPR may be disposed on the second planes PL2 of the block parts BL. Accordingly, the dummy parts SPR may be supported by the second planes PL2.

The cover part CV may cover the first insulation part IN1 and the second insulation part IN2. The first insulation part IN1 and the second insulation part IN2 may be disposed in an interior of the cover part CV. A potential of the cover part CV may be 0. That is, the cover part CV may be a ground.

The cover part CV may include a cover body CVB and a cover protrusion CVP. The cover body CVB may cover the first insulation part IN1 and the second insulation part IN2. The cover protrusion CVP may be disposed on an upper surface of the cover body CVB. The cover protrusion CVP may be disposed at a center of the upper surface of the cover body CVB.

A second opening OP2 may be defined on an upper surface of the cover protrusion CVP. By way of example, the second opening OP2 may have a partial shape of a circular column. When the cover body CVB covers the first and second insulation parts IN1 and IN2, the second part PT2 may be disposed in the second opening OP2. An outer surface of the second part PT2 may be covered by the cover protrusion CVP.

FIG. 8 is a perspective view of a portion of the accommodation part AP and the gas supply part GSP illustrated in FIG. 2. FIG. 9 is a perspective view of the gas supply part GSP, the accommodation part AP, and a nozzle assembly NOA illustrated in FIG. 2. FIG. 10A is a side view of a gas ejection part GEP illustrated in FIG. 9. FIG. 10B is a side view of the gas ejection part GEP according to an embodiment of the present disclosure.

By way of example, FIGS. 8 and 9 are perspective views illustrating a cross section of a portion corresponding to line III-III′ illustrated in FIG. 2.

By way of example, FIG. 8 is a perspective view of a state, in which the nozzle assembly NOA is not disposed in the accommodation groove AGR of the accommodation part AP, and FIG. 9 is a perspective view of a state, in which the nozzle assembly NOA is disposed in the accommodation groove AGR of the accommodation part AP.

A description of, among the components illustrated in FIGS. 8 to 10B, components that are the same as those described above while the above-described drawings are referenced will be omitted or simplified.

Referring to FIG. 8, the accommodation part AP may include a body BD and a plurality of support plates SPT. The accommodation groove AGR may be defined in an interior of the body BD. The accommodation groove AGR may have a shape corresponding to a portion of a rectangular shape.

Support plates SPT may be disposed on a lower surface of the body BD. The support plates SPT may extend in the second direction DR2, and may be spaced apart from each other in the first direction DR1. By way of example, the support plates SPT may be parallel to a plane that is defined by the first direction DRI and the second direction DR2.

A plurality of support grooves SGR may be defined on upper surfaces of the support plates SPT. The support grooves SGR defined in the support plates SPT, respectively, may be arranged in the second direction DR2. The support grooves SGR defined in different support plates SPTs may be disposed to correspond to each other in the first direction DR1.

Referring to FIGS. 9 and 10A, in FIGS. 9 and 10A, it is described that one nozzle assembly NOA is disposed in the accommodation groove AGR, but the present disclosure is not limited thereto, and a plurality of nozzle assemblies NOA may be disposed in the accommodation groove AGR.

The nozzle assembly NOA may be disposed in the accommodation groove AGR. The nozzle assembly NOA may be disposed on the support plates SPT. Opposite sides of the nozzle assembly NOA, which are opposite to each other in the first direction DR1, may be disposed on the upper surfaces of the support plates SPT. The support plates SPT may support the nozzle assembly NOA.

The support parts SPP of the nozzle assembly NOA may be disposed in the support grooves SGR. The support grooves SGR may have a shape corresponding to the support parts SPP. Accordingly, the nozzle assembly NOA may be coupled to the accommodation part AP.

Because the support parts SPP are disposed on the support grooves SGR, the nozzle assembly NOA may be fixed at a set position. Accordingly, the nozzle assembly NOA may accurately eject gas onto the substrate SUB. Accordingly, a deposition reliability of the substrate SUB may be improved.

Referring to FIG. 10B, the accommodation part AP may further include a plurality of dummy plates DPL. The dummy plates DPL may be disposed in the support grooves SGR. The dummy plates DPL may have a specific thickness. The nozzle assembly NOA may be disposed on the upper surfaces of the dummy plates DPL. Because the nozzle assembly NOA is disposed on the upper surfaces of the dummy plates DPL, a height of a lower surface of the nozzle assembly NOA may be increased. By disposing the dummy plates DPLs in the support grooves SGR, a distance between the nozzle assembly NOA and the substrate SUB (see FIG. 1) may be easily adjusted.

Referring to FIG. 10A, when the nozzle assembly NOA is disposed in the accommodation groove AGR, the gas supply part GSP may supply gas to the nozzle assembly NOA. The cover protrusion CVP may be connected to a gas supply pipe IOP. The gas supply pipe IOP may be connected to a second part PT2 (see FIG. 3) that is disposed in the second opening OP2 (see FIG. 3). The gas supply pipe IOP may be connected to a main passage MPS (see FIG. 4). The gas supply pipe IOP may supply gas to the main passage MPS (see FIG. 4).

Although not illustrated, a plurality of gas supply pipes IOP may be provided to correspond to the number of nozzle assemblies NOA, and each of the gas supply pipes IOP may be connected to a corresponding one of the nozzle assemblies NOA to supply gas.

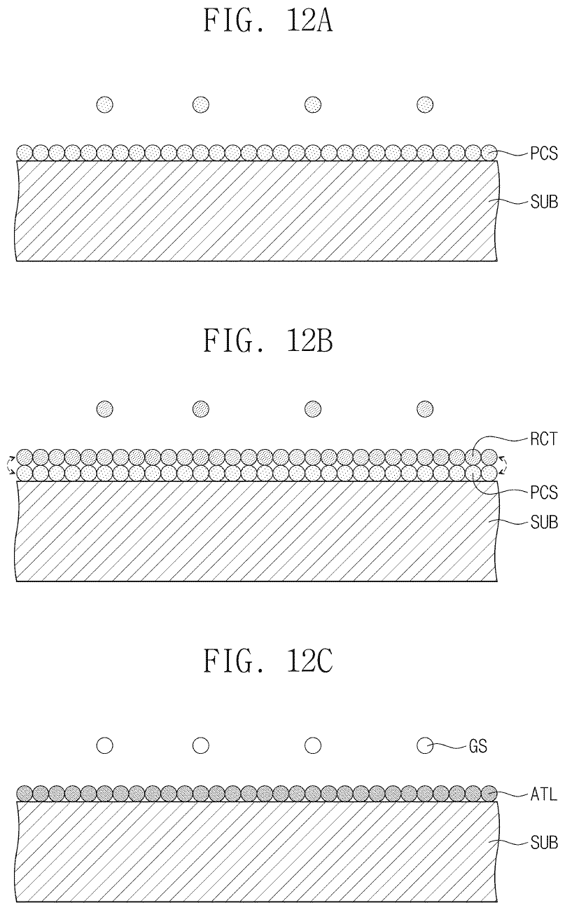

FIG. 11 is a view illustrating a process of depositing on a substrate SUB by using a deposition apparatus according to an embodiment of the present disclosure. FIGS. 12A to 12C are views schematically illustrating an atomic layer deposition method.

By way of example, FIG. 11 is a cross-sectional view of a portion corresponding to line I-I′ illustrated in FIG. 1.

By way of example, FIGS. 12A to 12C may be processes of forming a gate oxide dielectric film through an atomic layer deposition method.

For convenience of description, the support plates SPT (see FIG. 8) and cover protrusion CVP (see FIG. 3) of the accommodation part AP (see FIG. 8) are omitted.

A description of, among the components illustrated in FIGS. 11 to 12C, components that are the same as those described above while the above-described drawings are referenced will be omitted or simplified.

Referring to FIG. 11, the substrate SUB disposed on the stage STG may be a substrate of a display device. A gas ejection part GEP may be disposed on the substrate SUB. Gas may be ejected onto the substrate SUB in a state, in which the gas detection part GEP is fixed. Gas may be deposited on the upper surface of the substrate SUB while the stage STG and the substrate SUB are reciprocated in the second direction and an opposite direction to the second direction DR2. The gas may be deposited on the substrate SUB in units of an atomic layer. The deposition process will be described in detail below.

Referring to FIG. 12A, a precursor PCS may be ejected onto the substrate SUB in a gas form. The precursor PCS may be defined as a source gas. By way of example, the precursor PCS may include Al(CH₃)₃. The precursor PCS may be adsorbed onto the substrate SUB. By way of example, 2 Al(CH₃)₃ that is a molecule of Al(CH₃)₃ may be adsorbed onto the substrate SUB.

Only one layer of the precursor PCS may be adsorbed onto the substrate SUB. Even when Al(CH₃)₃ is continuously supplied as the precursor PCS, only one layer may be accumulated on the substrate SUB. This state may be defined as a self-limiting reaction. The remaining precursor PCS that is not adsorbed onto the substrate SUB and is left may be discharged to the outside.

Referring to FIG. 12B, a reactant RCT may be ejected onto a substrate SUB in a gas form. The reactant RCT may be defined as a reaction gas. By way of example, the reactant RCT may be H₂O. Three H₂O molecules may be supplied onto the substrate SUB. The reactant RCT may perform a chemical substitution reaction with the precursor PCS. By way of example, H₂O may perform a chemical substitution reaction with Al(CH₃)₃.

Like the precursor PCS, H₂O that is a reactant RCT is continuously supplied, so that only one layer may be adsorbed/substituted. The remaining reactant RCT may be discharged to the outside.

Referring to FIG. 12C, due to a chemical substitution reaction between the reactant RCT and the precursor PCS, one atomic layer ATL may be formed on the substrate SUB. By way of example, H₂O reacts with Al(CH₃)₃, and only Al₂O₃ is formed as a single layer on the substrate SUB, and gas GS (e.g., CH₄) remaining after the substitution reaction may be discharged to the outside.

Referring to FIG. 11, the plurality of nozzle assemblies NOA may eject the source gas or the reaction gas. Although seven nozzle assemblies NOA are illustrated, the number of the nozzle assemblies NOA is not limited thereto.

In the order in the second direction DR2, the gas ejected from the nozzle assemblies NOA disposed in the odd numbers and the gas ejected from the nozzle assemblies NOA disposed in the even numbers may be different from each other.

The nozzle assemblies NOA disposed in the even numbers may eject the precursor PCS of FIG. 12A in a gas form. The nozzle assemblies NOA disposed in the odd numbers may eject the reactant RCT of FIG. 12B in a gas form.

By way of example, when the substrate SUB is moved in the second direction DR2, the k-th nozzle assembly NOA may eject the source gas to deposit the precursor PCS (see FIG. 12A) on the substrate SUB, and then the (k+1)-th nozzle assembly NOA may eject the reaction gas to laminate the reactant RCT (see FIG. 12B) on the precursor PCS (see FIG. 12A). “k” may be an even number of two or more. When the substrate SUB is moved once in the second direction DR2, a deposition process may be performed three times by the nozzle assemblies NOA except for the first nozzle assembly NOA in an order in the second direction DR2.

The n-th nozzle assembly NOA may eject the source gas and the (n+1)-th nozzle assembly NOA may eject the reaction gas in an order in an opposite direction to the second direction DR2. “n” may be an even number of 2 or more. When the substrate SUB is moved once in an opposite direction to the second direction DR2, the deposition process may be performed three times by the nozzle assemblies NOA except for the first nozzle assembly NOA in an order in an opposite direction to the second direction DR2. That is, when the substrate SUB is reciprocated once in the second direction and an opposite direction to the second direction DR2, six deposition processes may be performed.

When gas is ejected onto the substrate SUB, a ratio of an amount of gas deposited on the substrate SUB to an amount of gas ejected from the nozzle assemblies NOA may be limited regardless of a width of the nozzle assemblies NOA in the second direction DR2. Accordingly, when the atomic layer ATL (FIG. 12C) is to be deposited to a specific thickness, the stage STG and the substrate SUB may be reciprocated a plurality of times, and a deposition process time may be lengthened.

In the case of the deposition apparatus DA according to an embodiment of the present disclosure, widths of the nozzle assemblies NOA in the second direction DR2 may be decreased. As the width of the nozzle assemblies NOA decreases, the number of nozzle assemblies NOA disposed in the accommodation groove AGR may be increased. Accordingly, when the substrate SUB is reciprocated once, the number of the deposition processes may be increased and the number of the reciprocations of the substrate SUB may be decreased. Accordingly, a time that is taken to deposit the atomic layer with a specific thickness on the substrate SUB may be shortened.

However, this is exemplary, and the nozzle assemblies NOA disposed in odd numbers may eject the source gas, and the nozzle assemblies NOA disposed in even numbers may eject the reaction gas.

A plurality of exhaust grooves VGR may be further defined on a lower surface of the accommodation part AP (see FIG. 11). The exhaust grooves VGR may be disposed on the nozzle assemblies NOA. The exhaust grooves VGR may extend in the third direction DR3 from upper portions of the accommodation grooves AGR. The exhaust grooves VGR and the accommodation grooves AGR may be continuously defined in the third direction DR3.

The exhaust grooves VGR may exhaust gas to the outside when the gas is ejected from the nozzle assemblies NOA. As the exhaust grooves VGR exhaust the gas to the outside, the source gas ejected from the even-numbered nozzle assemblies NOA may be prevented from flowing to the odd-numbered nozzle assemblies NOA, or the reaction gas ejected from the odd-numbered nozzle assemblies NOA may be prevented from flowing to the even-numbered nozzle assemblies NOA.

Although not illustrated, a curtain gas ejection part may be further disposed between the nozzle assemblies NOA. The gas ejected from the curtain gas ejection part may include an inert gas, such as argon gas or nitrogen gas, which does not react with the source gas and the reaction gas. The source gas or the reaction gas may be blocked from flowing to the outside by the gas ejected from the curtain gas ejection part.

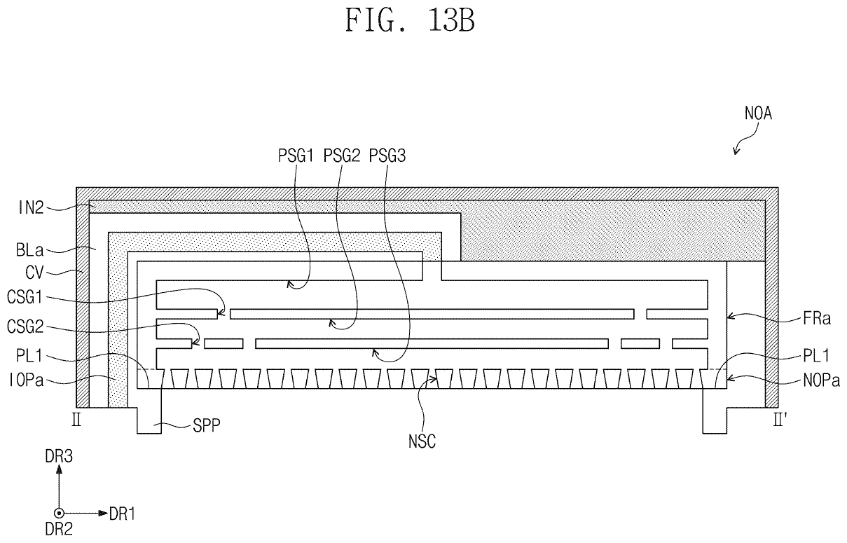

FIGS. 13A and 13B are cross-sectional views of a nozzle assembly NOA according to an embodiment of the present disclosure.

By way of example, FIGS. 13A and 13B are cross-sectional views of parts corresponding to line II-II′ illustrated in FIG. 2.

A description of, among the components illustrated in FIGS. 13A to 13B, components that are the same as those described above while the above-described drawings are referenced will be omitted or simplified.

Referring to FIGS. 13A and 13B, an electrode part FR, FRa, and a nozzle part NOP, NOPa, respectively, may be disposed on upper surfaces of the block parts BLa. Opposite sides of the nozzle part NOP, which are opposite to each other in the first direction DR1, may be disposed on the first planes PL1 of the block parts BLa.

The block parts BLa may cover opposite side surfaces of the nozzle part NOP, which are opposite to each other in the first direction DR1. The block parts BLa may cover opposite side surfaces of the electrode part FR, which are opposite to each other in the first direction DR1, and a portion of an upper surface of the electrode part FR. The block parts BLa may cover the main passage MPS.

The nozzle assembly NOA may further include a gas supply pipe IOPa. The gas supply pipe IOPa may be disposed in an interior of any one of the block parts BLa. By way of example, in FIGS. 13A and 13B, the gas supply pipe IOPa may be disposed in an interior of the block part BLa disposed on a left side thereof. Then, the gas supply part GSP (see FIG. 2) may be omitted.

The gas supply pipe IOPa may extend in the third direction DR3 and the first direction DR1. By way of example, when viewed from the second direction DR2, the gas supply pipe IOPa may have an inverted “L” shape. The gas supply pipe IOPa may be connected to the main passage MPS to transfer the gas supplied from the outside to the main passage MPS.

Because the nozzle assembly NOA includes the gas supply pipe IOPa, the gas supply part GSP (see FIG. 2) may be omitted, and thus the structure of the gas ejection part GEP may be simplified. Accordingly, the nozzle assembly NOA may be easily managed.

According to an embodiment of the present disclosure, the gas supplied to the first passage is supplied to the second passage through the first connection passage that is adjacent to opposite sides of the first passage, and the gas may be diffused to opposite sides of the second passage, which are opposed to each other in the first direction. Accordingly, the gas may be uniformly ejected onto the substrate. Accordingly, a thickness of the thin film deposited on the substrate may be uniform.

Although the present disclosure has been described with reference to the embodiments, it will be appreciated by an ordinary skilled in the art, to which the present disclosure pertains, that the present disclosure may be modified and changed within the scope of the appended claims without departing from the spirits and technical field of the present disclosure. Therefore, the technical scope of the present disclosure should not be limited to the detailed description of the specification, but should be determined by the claims.

What is claimed is:

1. A deposition apparatus comprising:
a stage; and
a nozzle assembly disposed on the stage, and including an electrode part extending in a first direction and a nozzle part disposed under the electrode part,
wherein a passage is defined in the electrode part,
wherein the passage includes:
a main passage defined on an upper surface of the electrode part, and extending in a downward direction;
a first passage extending from a lower portion of the main passage in the first direction;
first connection passages extending in the downward direction from a (1-1)-th area and a (1-2)-th area being adjacent to opposite sides of the first passage, which are opposite in the first direction; and
second passages extending in the first direction from lower portions of the first connection passages, and
wherein the nozzle part is disposed under the second passages.

2. The deposition apparatus of claim 1, wherein the (1-1)-th area and the (1-2)-th area are disposed between the opposite sides of the first passage, which are opposite to each other in the first direction, and a center of the first passage.

3. The deposition apparatus of claim 2, wherein a plurality of nozzle passages defined in the nozzle part extends in the downward direction from the second passages.

4. The deposition apparatus of claim 2, wherein the passage further includes:
second connection passages extending in the downward direction from (2-1)-th areas and (2-2)-th areas being adjacent to opposite sides of the second passages, which are opposite to each other in the first direction; and
third passages extending in the first direction from the second connection passages, and
wherein a plurality of nozzle passages defined in the nozzle part extends in the downward direction from the third passages.

5. The deposition apparatus of claim 4, wherein the (2-1)-th areas and the (2-2)-th areas are disposed between the opposite sides of the second passages, which are opposite to each other in the first direction, and centers of the second passages.

6. The deposition apparatus of claim 1, wherein the nozzle assembly includes:
first insulation parts extending in the first direction, and disposed on opposite sides of the nozzle part, which are opposite to each other in a second direction crossing the first direction; and
second insulation parts disposed on the first insulation parts, and covering the electrode part,
wherein the first insulation parts include:
a plurality of bar parts extending in the first direction, and spaced apart from each other in the second direction; and
protrusions extending from sides of the bar parts facing each other, and
wherein the protrusions are disposed in grooves defined on opposite sides of the nozzle parts, which are opposite to each other in the second direction.

7. The deposition apparatus of claim 6, wherein the first insulation parts further include:
a plurality of block parts disposed on opposite sides of the bar parts, which are opposite to each other in the first direction; and
a plurality of support parts extending downward from lower surfaces of the block parts.

8. The deposition apparatus of claim 7, wherein the block parts and the bar parts are coupled to each other to be separable.

9. The deposition apparatus of claim 7, further comprising:
an accommodation part disposed on the stage, and including a body, in which an accommodation groove accommodating the nozzle assembly is defined, and a plurality of support plates disposed on a lower surface of the body, extending in the first direction, and spaced apart from each other in the second direction.

10. The deposition apparatus of claim 9, wherein opposite sides of the nozzle assembly, which are opposite to each other in the first direction, are disposed on an upper surface of the support plate, and
wherein the support parts are disposed in a plurality of support grooves defined on the upper surface of the support plate.

11. The deposition apparatus of claim 10, wherein the accommodation part further includes:
a plurality of dummy plates disposed in the support grooves, and
wherein the support parts are disposed on upper surfaces of the dummy plates.

12. The deposition apparatus of claim 9, wherein an exhaust part is further defined in the accommodation part, and
wherein the exhaust part is disposed at an upper portion of the accommodation groove, and the exhaust part and the accommodation groove are defined in the downward direction crossing a plane defined by the first direction and the second direction.

13. The deposition apparatus of claim 7, wherein a gas supply passage is defined in the block parts, and the main passage extends in the downward direction from the gas supply passage.

14. The deposition apparatus of claim 6, wherein the nozzle assembly further includes:
a cover part covering the first insulation part and the second insulation part.

15. The deposition apparatus of claim 1, wherein a plurality of nozzle assemblies is provided, and the nozzle assemblies are arranged in a second direction crossing the first direction, and
wherein gas ejected from any one of the nozzle assemblies is different from gas ejected from the remaining nozzle assemblies.

16. The deposition apparatus of claim 1, further comprising:
a gas supply part disposed on the nozzle assembly, and including a gas supply pipe,
wherein the gas supply pipe and the nozzle assembly are connected to each other.

17. A deposition apparatus comprising:
a stage;
an accommodation part disposed on the stage, and including a body, in which an accommodation groove is defined, and a support plate disposed on a lower surface of the body;
a nozzle assembly extending in a first direction, and disposed in the accommodation groove; and
a gas supply part disposed on an upper surface of the accommodation part,
wherein opposite sides of the nozzle assembly, which are opposite to each other in the first direction, are disposed in support grooves defined in the support plate.

18. The deposition apparatus of claim 17, wherein the nozzle assembly includes:
an electrode part, in which a passage is defined in an interior thereof;
a nozzle part disposed under the electrode part;
first insulation parts disposed in grooves defined on opposite surfaces of the nozzle part, which are opposite to each other in a second direction crossing the first direction; and
second insulation parts disposed on the first insulation parts, and covering the electrode part.

19. The deposition apparatus of claim 18, wherein the passage includes:
a main passage connected to the gas supply part;
a first passage extending from a lower portion of the main passage in the first direction;
a second passage disposed under the first passage, and extending in the first direction; and
first connection passages extending in a downward direction from a (1-1)-th area and a (1-2)-th area being adjacent to opposite sides of the first passage, which is opposite to each other in the first direction, and connected to the first passage and the second passage.

20. The deposition apparatus of claim 19, wherein nozzle passages defined in the nozzle extend in the downward direction from the second passage.
